(19) United States
(12) Patent Application Publication
(10) Pub. No.: US 2011/0269320 A1
(43) Pub. Date: Nov. 3, 2011

(54) MEANS FOR SECURING A POWER SUPPLY TO A BUS BAR

(76) Inventors: Knut Roettger, Hertfordshire (GB); Iqbal Kazi, Hertfordshire (GB); Peter Sean Comiskay, Hertfordshire (GB)

(21) Appl. No.: 12/744,382

(22) PCT Filed: Nov. 26, 2008
(86) PCT No.: PCT/GB08/03946

§ 371 Date: May 9, 2011

(30) Foreign Application Priority Data
Nov. 27, 2007 (GB) 0723214.3

(51) Int. Cl. H01R 12/70; H05K 5/00; H01R 4/30

(52) U.S. Cl. 439/76.2; 439/801; 174/520

(57) ABSTRACT

Means for securing a power supply terminal to a bus bar, the securing means comprising: a securing base; a stud rigidly mounted in the securing base; and a securing nut, wherein the stud is arranged to receive, in use, a bus bar mounted on a circuit board and a power supply terminal, the bus bar and terminal being secured in electrical contact with one another by the securing nut.

The present invention relates to means for securing a power supply to a bus bar, which is attached to a circuit board, with minimal stress or torque being transmitted directly to the circuit board and components thereon during and after installation.

In many high power applications power is commonly supplied to a circuit board via a bus bar attached to the circuit board. The power supply generally has a terminal which is used to connect the power supply to the bus bar. Ideally, the terminal is secured to the bus bar to ensure a good electrical connection between the power supply means and the bus bar, and hence the circuit board and components mounted thereon.

However, one problem in securing a power supply terminal to a bus bar in such a manner is that when any securing means is tightened in order to ensure a good electrical connection, undesirable stress or torque is often directly transmitted to the bus bar and hence to components mounted on the circuit board that the bus bar is attached to, potentially damaging the circuit board, solder joints or components.

An object of the present invention is, therefore, to provide a securing means, which does not directly transmit stress or torque to the bus bar, circuit board or components mounted thereon whilst still ensuring a good, reliable and secure connection.

According to the present invention there is provided means for securing a power supply terminal to a bus bar, the securing means comprising: a securing base; a stud rigidly mounted in the securing base; and a securing nut, wherein the stud is arranged to receive, in use, a bus bar mounted on a circuit board and a power supply terminal, the bus bar and terminal being secured in electrical contact with one another by the securing nut.

The present invention overcomes the problem of stress or torque being directly transmitted to the bus bar and hence circuit board when securing the power supply terminal to it by providing for both the bus bar and power supply terminal to be secured onto a separate stud, which is not attached to the bus bar or circuit board.

By securing the bus bar and power supply terminal onto a separate stud, any stress or torque applied to the stud during a tightening operation of the securing nut is not directly transmitted to the bus bar, circuit board or components mounted thereon.

An example of the invention will now be described with reference to accompanying drawings, in which:

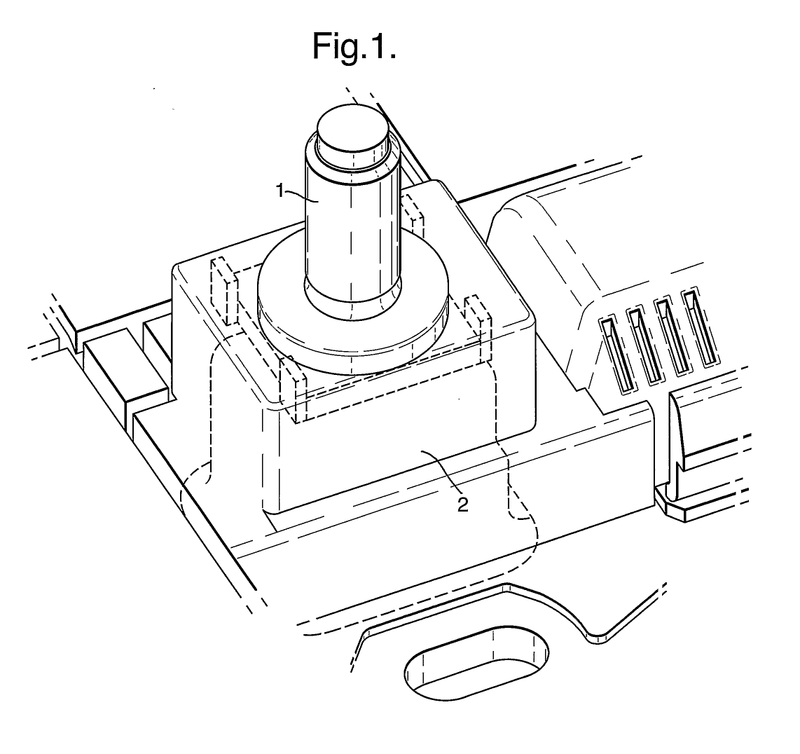

FIG. 1 illustrates a stud rigidly mounted in a securing base according to the present invention;

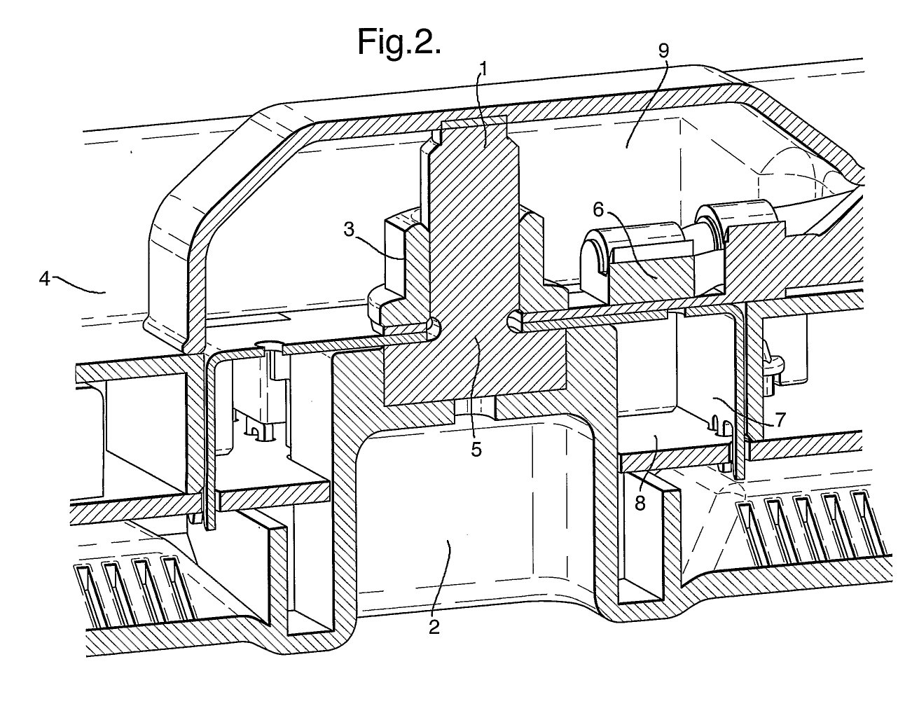

FIG. 2 is a cut-away illustration showing a bus bar and power supply terminal secured to one another, according to the present invention;

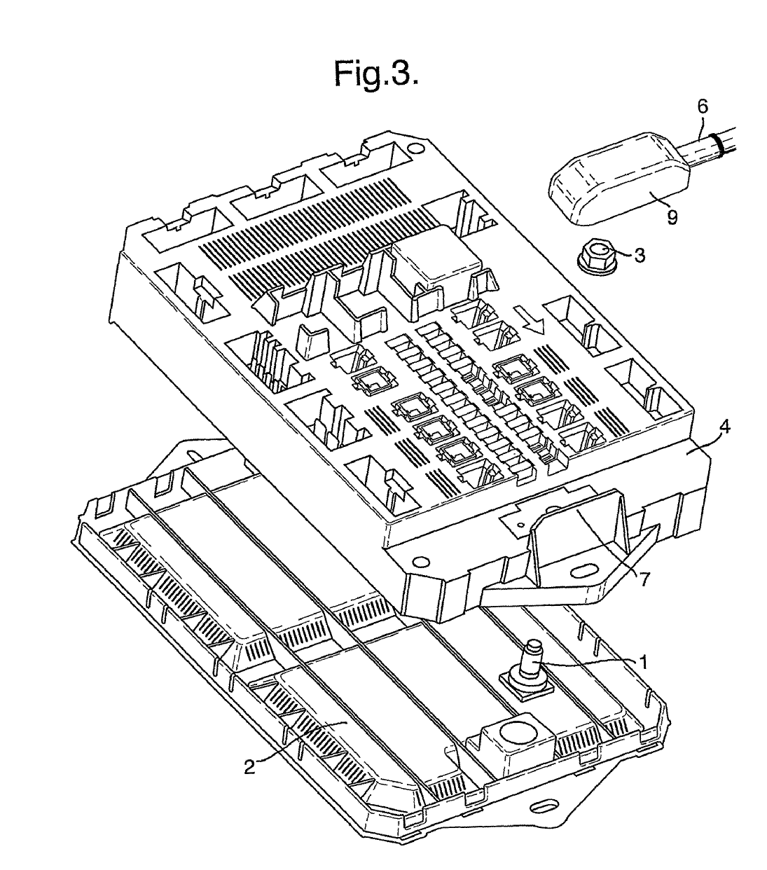

FIG. 3 is an exploded view of the securing means components; and

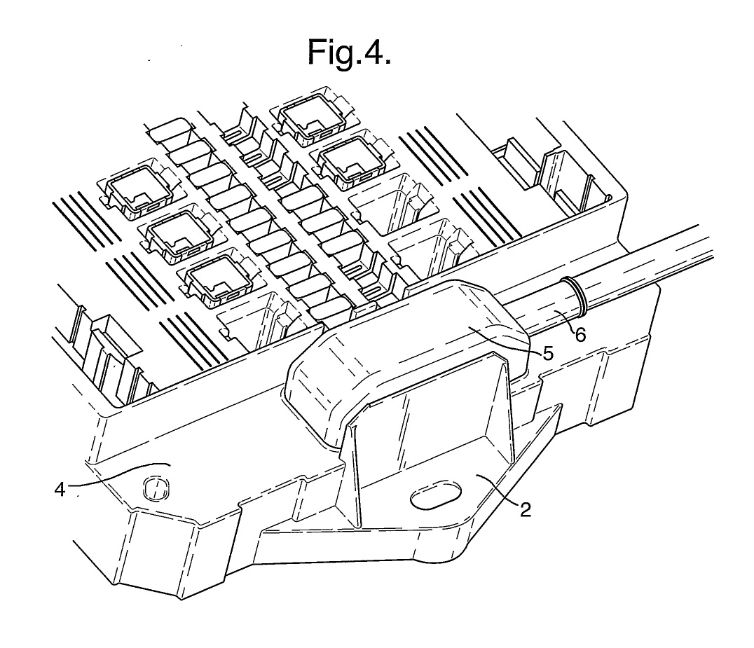

FIG. 4 shows a protective cover protecting the power supply terminal and bus bar after having been secured to one another.

The invention relates in particular to a securing means for securing a power supply means 6 to a bus bar 7 mounted on a circuit board 8. In particular, the invention provides a means for securing a power supply terminal 6 to a bus bar 7, without directly transmitting any stress or torque to the bus bar 7 or to the circuit board 8 it is mounted on.

In one example of the present invention, the securing means also comprises a housing for a circuit board 8, the housing further comprising a removable housing cover 4 and a securing base 2. The circuit board 8 is arranged within the housing cover 4, the circuit board having a bus bar 7 mounted onto it, at least a part of which is preferably exposed outside of the housing cover 4.

A stud 1 is integrated within the securing base 2, ideally being rigidly secured so that it cannot move. One way of achieving this might be for plastic material to be moulded around the stud 1 in a single injection moulding cycle to secure it.

The stud 1 and circuit board 8 are arranged in the securing base 2 and housing cover 4 respectively such that when the cover is fitted onto the securing base 2, the bus bar 7 is aligned with the stud 1, which fits through a hole 5 provided in the bus bar 7 to accommodate it.

The power supply means ideally has a terminal 6, which is then fitted over the stud 1 so that it rests on top of the bus bar 7, thereby forming an electrical contact with the bus bar 7. A securing nut 3 is then fitted to the stud 1 and tightened against the power supply terminal 6 thereby securing the power supply terminal 6 to the bus bar 7 and hence to the securing base 2.

The securing nut 3 shown in FIG. 2 has a flange, which helps to spread the stress when it is tightened. However, similar means, for example a washer (not shown) may also be provided on the stud 1 underneath the securing nut 3 as required.

Due to the arrangement of the present invention, any torque created in tightening the securing nut 3 is transmitted to the securing base 2, where the stud 1 is secured, via the stud. Accordingly, no direct stress or torque is transmitted to the bus bar 7, circuit board 8, or any components mounted thereon.

A protective cover 9, for example made from rubber or similar, may also be provided to protect the bus bar 7 and power supply terminal 6.

An advantage provided by the securing means of the present invention is that reliability of the circuit board 8 is improved as a result of the reduced occurrence of fractured solder joints or PCB copper trace fractures, previously caused by stress and torque transmitted when securing the power supply terminal 6 and bus bar 7 to one another.

Another advantage is that the present invention allows an increased tightening torque to be applied to the securing nut 3 and hence a more secure and better connection between the power supply terminal 6 and bus bar 7, resulting in a reduced volt-drop and hence a reduced temperature rise across the connection.

1. A securing means for securing a power supply terminal to a bus bar, the securing means comprising:
a securing base;
a stud rigidly mounted in the securing base;
and a securing nut, wherein the stud is arranged to receive, in use, a bus bar mounted on a circuit board and a power supply terminal, the bus bar and terminal being secured in electrical contact with one another by the securing nut.

2. The securing means of claim 1, further comprising a washer arranged to fit, in use, onto the stud between the securing nut and the securing base.

3. The securing means of claim 1, wherein the securing nut has a flange which is free to rotate about the securing nut, in use, to prevent the transfer of torque through the flange.

4. The securing means of claim 1, further including a housing for the circuit board and a housing cover.

5. The securing means of claim 4, wherein the circuit board is arranged within the housing cover.

6. The securing means of claim 5, wherein the housing cover is removably fitted to the securing base.

7. The securing means of claim 1, further comprising a protective cover to protect the bus bar and power supply terminal once secured to one another.

8. The securing means of claim 4 located within a junction box.

9. The securing means of claim 4 located within a junction box located within an automobile.
